(19) United States
(12) Patent Application Publication
(10) Pub. No.: US 2026/0204458 A1
(43) Pub. Date: Jul. 16, 2026

(54) WIRE HARNESS AND WIRE HARNESS MANUFACTURING METHOD

(71) Applicant: Yazaki Corporation, Tokyo (JP)

(72) Inventors: Katsunori SATO, Shizuoka (JP); Tatsuya OGA, Shizuoka (JP)

(73) Assignee: Yazaki Corporation, Tokyo (JP)

(21) Appl. No.: 19/563,440

(22) Filed: Mar. 11, 2026

Related U.S. Application Data
(63) Continuation of application No. PCT/JP2025/004308, filed on Feb. 10, 2025.

(30) Foreign Application Priority Data
Mar. 14, 2024 (JP) 2024-039878

(51) Int. Cl. H01B 13/012; H01B 7/00; H01B 7/04; H01B 7/18

(52) U.S. Cl. CPC H01B 13/01209; H01B 7/0018; H01B 7/04; H01B 7/1805

(57) ABSTRACT

A wire harness includes: a flat wiring member formed in a U shape including a first portion, a second portion, and an intermediate portion; a first case that holds the first portion; and a second case that holds the second portion. The first case and the second case can be engaged with each other in a state where the flat wiring member has a straight line shape. The flat wiring member having a straight line shape includes a first folded portion and a second folded portion. The intermediate portion is folded along a folding line in the first folded portion, the folding line extending in an extending direction in which the first portion extends. The second portion is folded, in the second folded portion, along a folding line orthogonal to the extending direction so as to allow a part of the second portion to overlap with the intermediate portion.

### CROSS-REFERENCE TO RELATED APPLICATION(S

This application is a continuation application of International Application No. PCT/JP2025/004308 filed on February 10, 2025 which claims the benefit of priority from Japanese Patent Application No. 2024-039878 filed on March 14, 2024 and designating the U.S., the entire contents of which are incorporated herein by reference.

### BACKGROUND OF THE INVENTION

### 1. Field of the Invention

The present invention relates to a wire harness and a wire harness manufacturing method.

### 2. Description of the Related Art

There are conventionally known flat wiring members such as a flexible printed circuit board. JP 2015 – 170 699 A discloses a flexible printed circuit board capable of easily implementing elongated wire arrangement. The flexible printed circuit board of JP 2015 – 170699 A includes: a first band-shaped member and a second band-shaped member each having a conductive portion and an insulating portion covering the conductive portion; and a first coupling member that couples a first end of the first band-shaped member and a first end of the second band-shaped member.

The flat wiring member formed in a U shape is desired to be elongated into a straight line shape. When the flat wiring member formed in the U shape is used, the manufacturing cost and the mounting cost of the flat wiring member can be reduced.

### SUMMARY OF THE INVENTION

An object of the present invention is to provide a wire harness and a wire harness manufacturing method capable of elongating a flat wiring member formed in a U shape into a straight line shape.

In order to achieve the above mentioned object, a wire harness according to one aspect of the present invention includes a flat wiring member formed in a U shape, the flat wiring member including a first portion having a straight line shape, a second portion having a straight line shape, and an intermediate portion connecting an end of the first portion and an end of the second portion; a first case that holds the first portion; and a second case that holds the second portion, wherein the first case and the second case can be engaged with each other in a state where the flat wiring member has a straight line shape, the flat wiring member having a straight line shape has a configuration in which the second portion extends on an extension line of the first portion in plan view, the flat wiring member having a straight line shape includes a first folded portion and a second folded portion, the intermediate portion is folded along a folding line in the first folded portion, the folding line extending in an extending direction in which the first portion extends, and the second portion is folded, in the second folded portion, along a folding line orthogonal to the extending direction so as to allow a part of the second portion to overlap with the intermediate portion.

In order to achieve the above mentioned object, a wire harness manufacturing method according to another aspect of the present invention includes a step of accommodating, in a first case, a first portion having a straight line shape in a flat wiring member formed in a U shape; a step of accommodating, in a second case, a second portion having a straight line shape in the flat wiring member; a step of forming a first folded portion at an intermediate portion in the flat wiring member that connects the first portion and the second portion by overlapping the first case and the second case; and a step of forming a second folded portion in the second portion by rotating the first case and the second case relative to each other, wherein the step of forming the first folded portion folds the intermediate portion along a folding line in an extending direction of the first portion, and the step of forming the second folded portion folds the second folded portion along a folding line orthogonal to the extending direction so as to allow a part of the second portion to overlap with the intermediate portion.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a perspective view of a wire harness according to an embodiment;

FIG. 2 is a perspective view illustrating a flat wiring member having a straight line shape according to the embodiment;

FIG. 3 is a plan view of the flat wiring member according to the embodiment;

FIG. 4 is a plan view of a case according to the embodiment;

FIG. 5 is a perspective view of the case according to the embodiment;

FIG. 6 is a plan view of the wire harness according to the embodiment;

FIG. 7 is a plan view of the wire harness according to the embodiment;

FIG. 8 is a plan view of the wire harness according to the embodiment;

FIG. 9 is a cross-sectional view of the wire harness according to the embodiment;

FIG. 10 is a perspective view of the flat wiring member in which a first folded portion is formed;

FIG. 11 is a cross-sectional view of the wire harness according to the embodiment;

FIG. 12 is a perspective view of the wire harness according to the embodiment;

FIG. 13 is a cross-sectional view of the wire harness according to the embodiment; and

FIG. 14 is a perspective view of the wire harness according to the embodiment.

### DETAILED DESCRIPTION OF THE PREFERRED EMBODIMENTS

Hereinafter, a wire harness and a wire harness manufacturing method according to an embodiment of the present invention will be described in detail with reference to the drawings. Note that the present invention is not limited by the embodiment. Moreover, components in the following embodiment include those that are easily conceivable for those skilled in the art or substantially identical.

### Embodiment

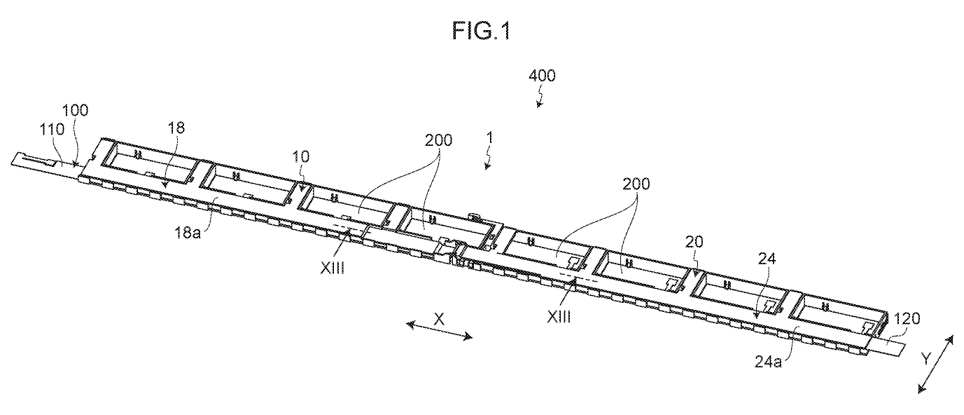

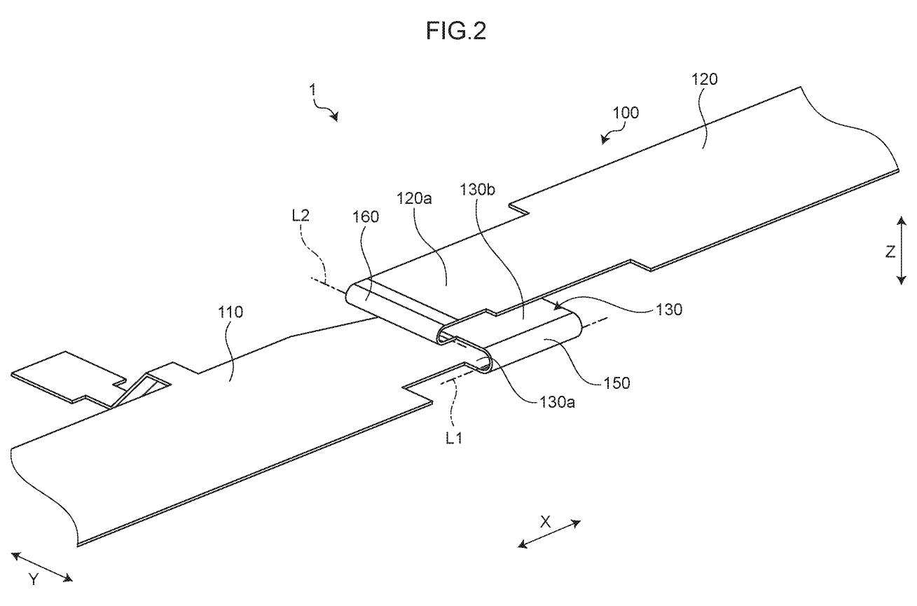

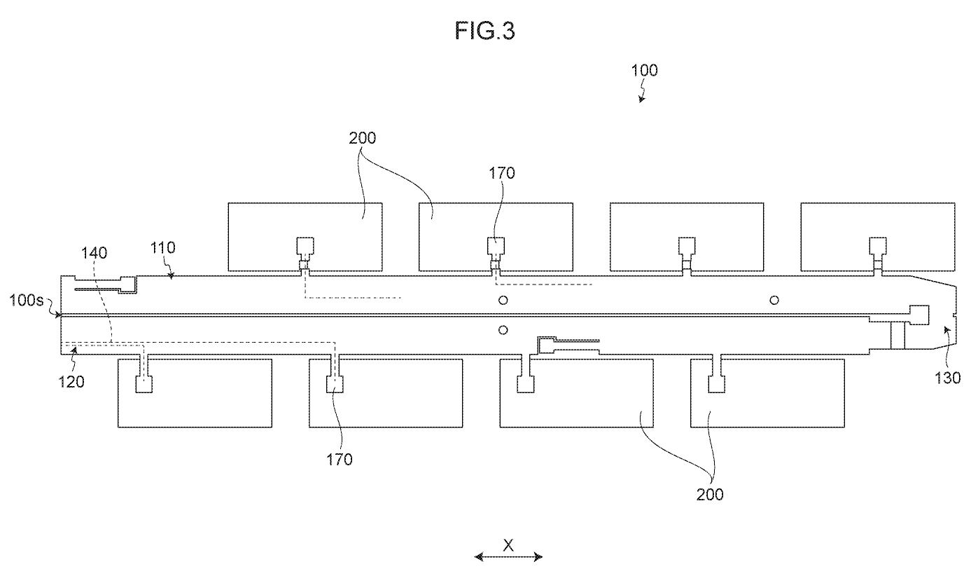

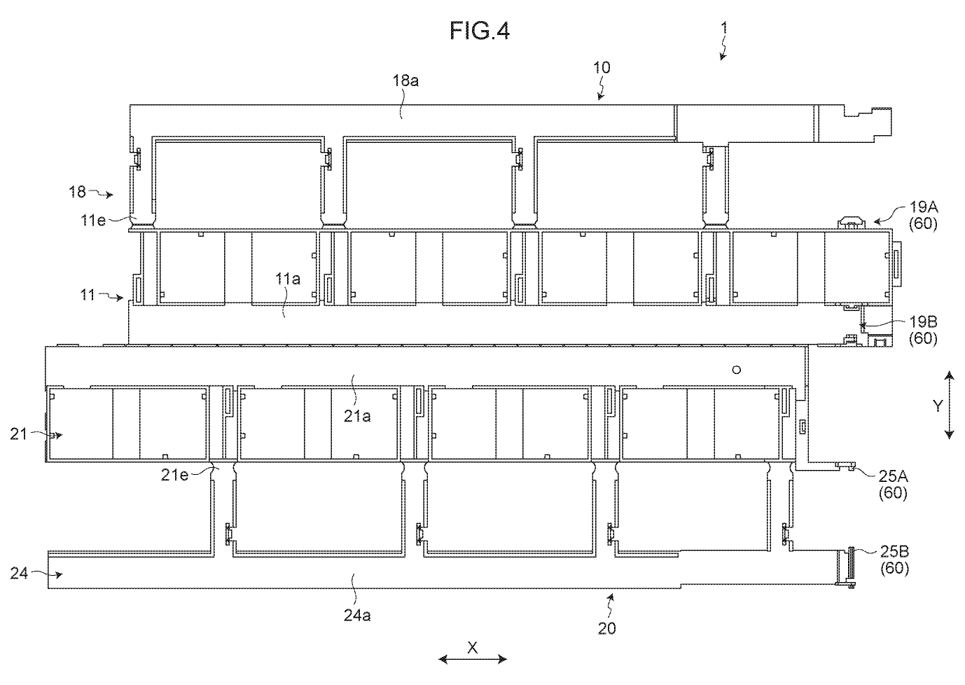

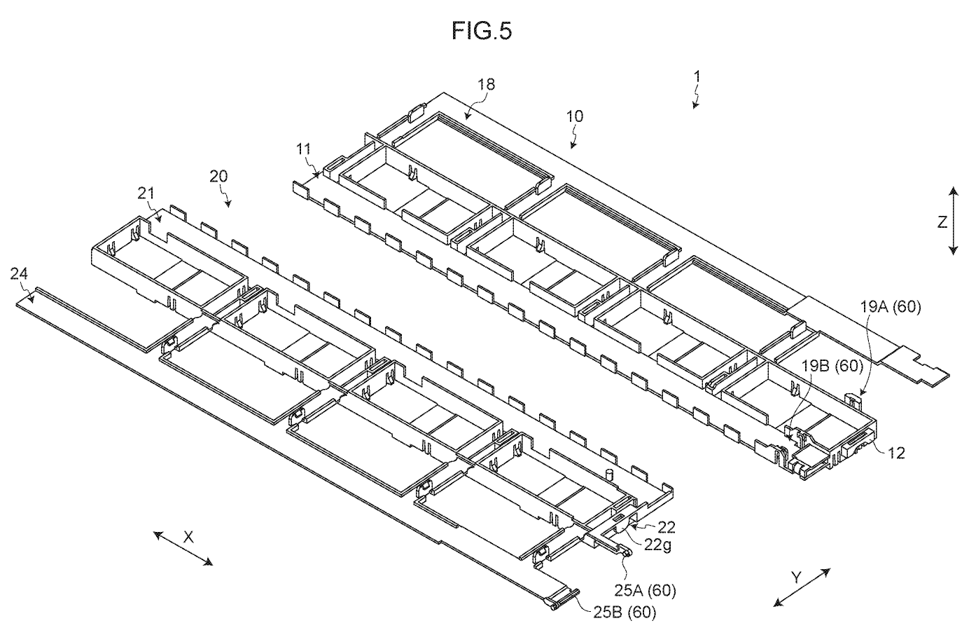

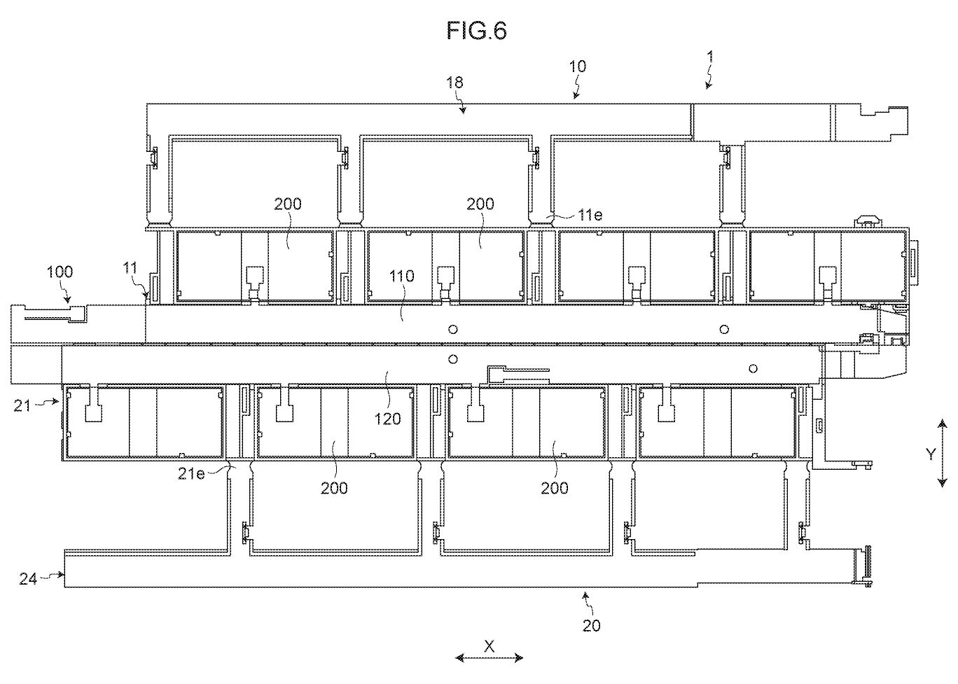

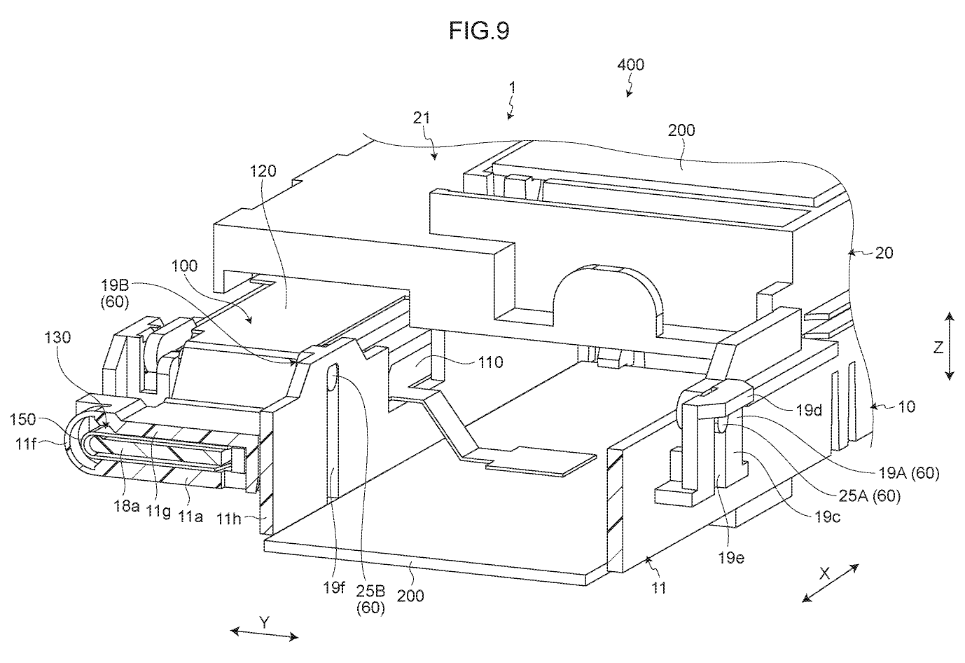

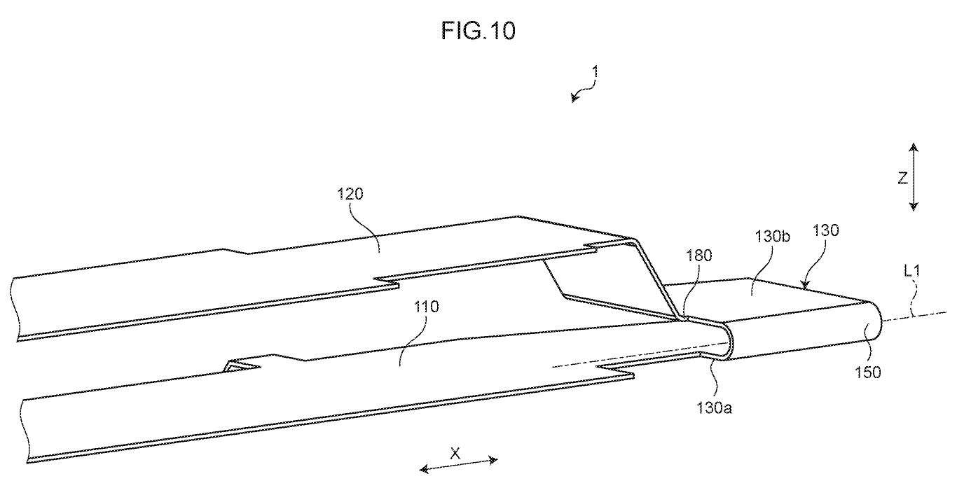

An embodiment will be described with reference to FIGS. 1 to 14. The present embodiment relates to a wire harness and a wire harness manufacturing method. FIG. 1 is a perspective view of a wire harness according to the embodiment, FIG. 2 is a perspective view of a flat wiring member having a straight line shape according to the embodiment, FIG. 3 is a plan view of the flat wiring member according to the embodiment, FIG. 4 is a plan view of a case according to the embodiment, FIG. 5 is a perspective view of a case according to the embodiment, FIGS. 6 to 8 are plan views of the wire harness according to the embodiment, FIG. 9 is a cross-sectional view of the wire harness according to the embodiment, and FIG. 10 is a perspective view of the flat wiring member in which a first folded portion is formed.

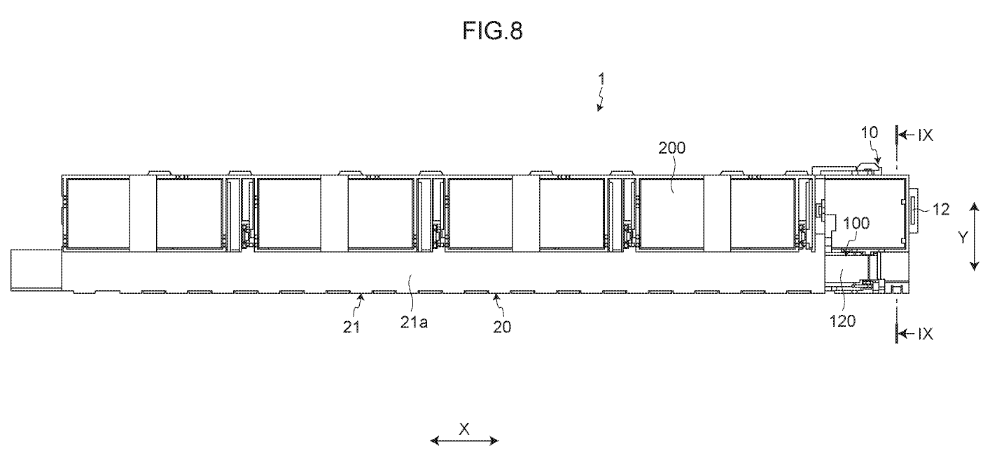

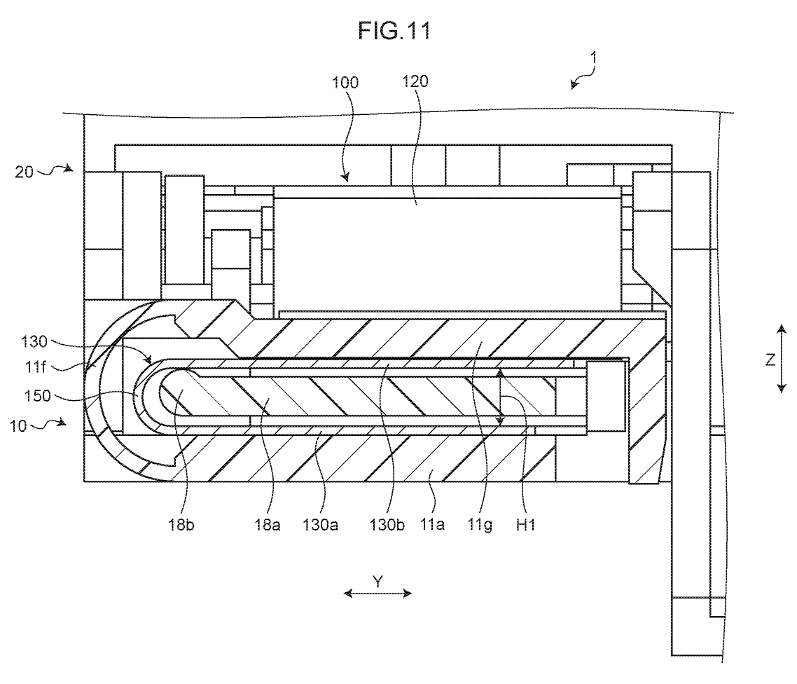

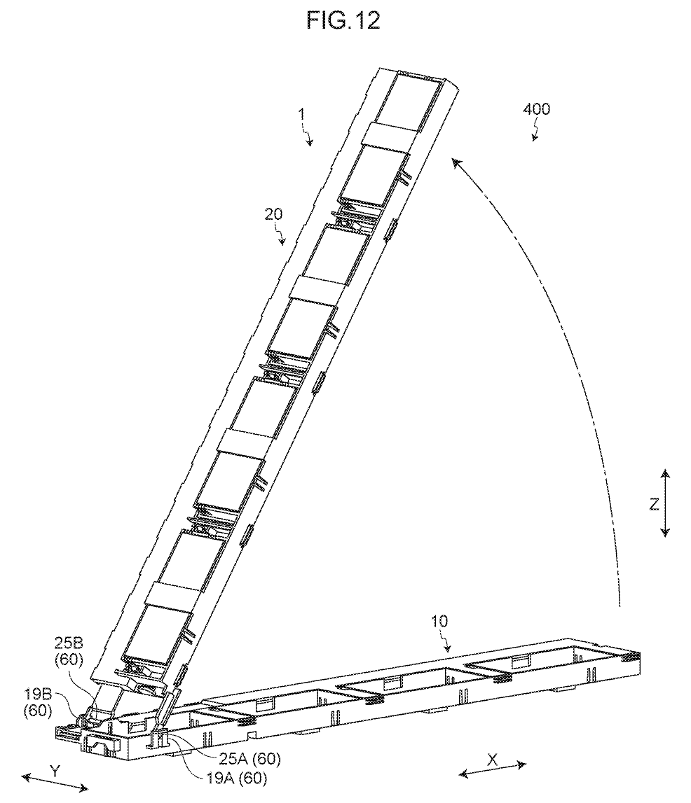

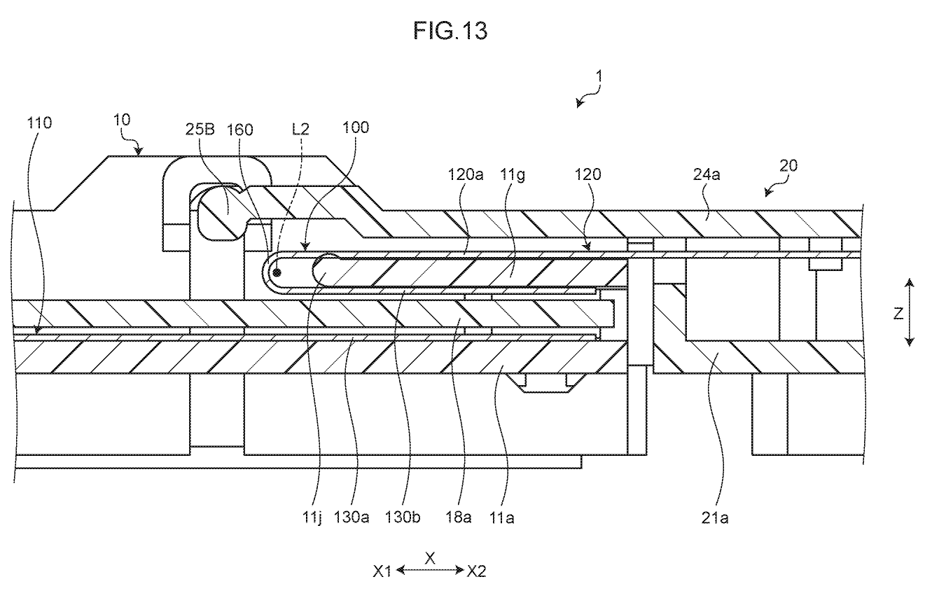

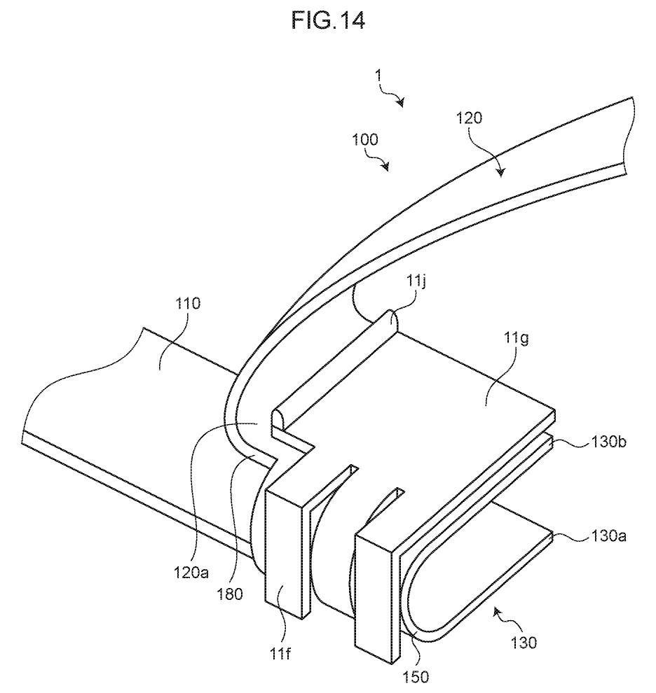

FIG. 11 is a cross-sectional view of the wire harness according to the embodiment, FIG. 12 is a perspective view of the wire harness according to the embodiment, FIG. 13 is a cross-sectional view of the wire harness according to the embodiment, and FIG. 14 is a perspective view of the wire harness according to the embodiment. FIGS. 9 and 11 each illustrate a cross section taken along line IX-IX in FIG. 8. FIG. 13 illustrates a cross section taken along line XIII-XIII of FIG. 1.

As illustrated in FIG. 1, a wire harness 1 of the embodiment includes a flat wiring member 100, a first case 10, and a second case 20. As described below, the first case 10 and the second case 20 of the present embodiment can transform the flat wiring member 100 formed in a U shape into a straight line shape and hold the transformed flat wiring member 100. The first case 10 and the second case 20 are configured to engage with each other while holding the flat wiring member 100 having a straight line shape. The flat wiring member 100 in FIG. 1 is held in a straight line shape by the two cases 10 and 20.

FIG. 2 illustrates a main part of the flat wiring member 100 held in a straight line shape as illustrated in FIG. 1. FIG. 3 illustrates the U-shaped flat wiring member 100 before being transformed into a straight line shape. The flat wiring member 100 is, for example, a flexible printed circuit board (FPC). The flat wiring member 100 of the present embodiment is disposed in a battery module and detects the voltage and temperature of the battery cell of the battery module.

When the flat wiring member 100 is an FPC, the flat wiring member 100 includes a base film, a conductive layer, and a coverlay. The conductive layer is sandwiched and protected by the base film and the coverlay. The conductive layer is, for example, a conductive metal foil, and has a circuit pattern including a plurality of detection lines 140. The flat wiring member 100 has flexibility and can be bent to be wired.

The flat wiring member 100 illustrated in FIG. 3 has a substantially U shape in plan view. The flat wiring member 100 includes a first portion 110, a second portion 120, and an intermediate portion 130. The first portion 110 and the second portion 120 in plan view have substantially rectangular shapes. The flat wiring member 100 includes a slit 100s formed between the first portion 110 and the second portion 120.

The intermediate portion 130 connects an end of the first portion 110 having a straight line shape and an end of the second portion 120 having a straight line shape. The intermediate portion 130 in plan view has a substantially trapezoidal shape. The intermediate portion 130 has a tapered shape whose width narrows as being farther away from the first portion 110 and the second portion 120 in the extending direction X. The extending direction X is a direction in which the first portion 110 extends and is a longitudinal direction of the first portion 110. In the flat wiring member 100 having an initial shape before transformation, the first portion 110 and the second portion 120 extend in the same extending direction X and are aligned in a width direction Y. The width direction Y is a direction orthogonal to the extending direction X, and is a width direction of the first portion 110 and the second portion 120.

The flat wiring member 100 of the present embodiment has a branch portion 170 connected to a busbar 200. The branch portion 170 extends in the width direction Y from the first portion 110 and the second portion 120. The distal end of the branch portion 170 is connected to the busbar 200 by solder, etc.

FIGS. 4 and 5 illustrate the first case 10 and the second case 20 of the present embodiment. The first case 10 and the second case 20 are molded using an insulating synthetic resin, for example. The first case 10 includes a main body 11 and a cover 18. The main body 11 and the cover 18 are integrally molded, for example. In the first case 10 of the present embodiment, the main body 11 and the cover 18 are connected to each other via a hinge portion 11e. The main body 11 includes a support wall 11a that supports the first portion 110 of the flat wiring member 100. The support wall 11a is formed in a straight line shape in the extending direction X. The cover 18 includes a facing wall 18a that covers the support wall 11a. The first portion 110 of the flat wiring member 100 is accommodated and held between the support wall 11a and the facing wall 18a.

At an end of the main body 11 in the extending direction X, there are provided a first shaft support portion 19A and a second shaft support portion 19B. The first shaft support portion 19A rotatably supports a first rotation shaft 25A of the second case 20. The second shaft support portion 19B rotatably supports a second rotation shaft 25B of the second case 20.

The second case 20 according to the embodiment includes a main body 21 and a cover 24. The main body 21 and the cover 24 are integrally molded, for example. In the second case 20 of the present embodiment, the main body 21 and the cover 24 are connected to each other via a hinge portion 21e. The main body 21 includes a support wall 21a that supports the second portion 120 of the flat wiring member 100. The support wall 21a is formed in a straight line shape in the extending direction X. The cover 24 includes a facing wall 24a that covers the support wall 21a. The second portion 120 of the flat wiring member 100 is accommodated and held between the support wall 21a and the facing wall 24a.

At an end of the main body 21 in the extending direction X, there is provided a first rotation shaft 25A. At an end of the cover 24 in the extending direction X, there is provided a second rotation shaft 25B. The first rotation shaft 25A protrudes in the width direction Y from the side surface of the main body 21. The second rotation shaft 25B extends in the width direction Y so as to cross the end of the cover 24. Both ends of the second rotation shaft 25B are supported by the second shaft support portion 19B.

In the wire harness 1 according to the embodiment, the two shaft support portions 19A and 19B of the first case 10 and the two rotation shafts 25A and 25B of the second case 20 constitute the rotating structure 60. The rotating structure 60 enables relative rotation of the two cases 10 and 20 as illustrated in FIG. 12.

As illustrated in FIG. 5, the first case 10 includes a first engagement portion 12, and the second case 20 includes a second engagement portion 22. The first engagement portion 12 is disposed at an end of the main body 11 in the extending direction X. The second engagement portion 22 is disposed at an end of the main body 21 in the extending direction X. The two engagement portions 12 and 22 are engaged with each other in a second relative position illustrated in FIG. 1.

FIG. 6 illustrates the flat wiring member 100 assembled to the first case 10 and the second case 20. The first case 10 and the second case 20 illustrated in FIGS. 4 and 6 are aligned in the width direction Y. In the present specification, regarding the first case 10 and the second case 20, a relative position in which the two cases 10 and 20 are aligned in the width direction Y is denoted as a first relative position. As illustrated in FIG. 4, when the two cases 10 and 20 are disposed in the first relative position, the support wall 11a of the first case 10 and the support wall 21a of the second case 20 are aligned in the width direction Y.

The first portion 110 of the flat wiring member 100 is accommodated in the main body 11 of the first case 10 and is supported by the support wall 11a. The step of accommodating the first portion 110 in the first case 10 is executed by an operator, for example. The second portion 120 of the flat wiring member 100 is accommodated in the main body 21 of the second case 20 and is supported by the support wall 21a. The step of accommodating the second portion 120 in the second case 20 is executed by an operator, for example. The two accommodating steps are executed in a state where the two cases 10 and 20 are held by a jig plate, for example.

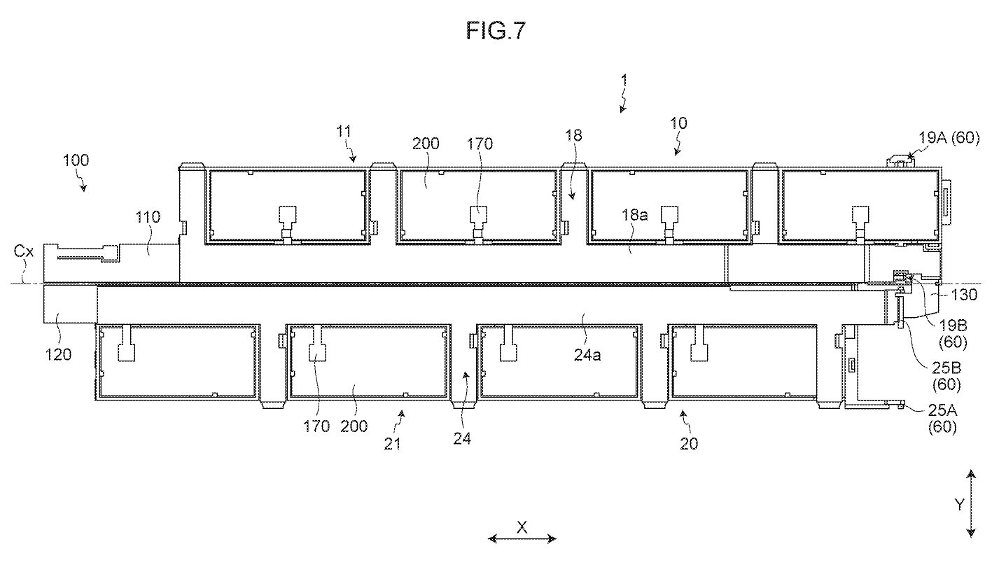

When the flat wiring member 100 has been accommodated in the two cases 10 and 20, a closing step of closing the covers 18 and 24 is executed. In the closing step, the cover 18 of the first case 10 is assembled to the main body 11 while bending the hinge portion 11e. In the closing step, the cover 24 of the second case 20 is assembled to the main body 21 while bending the hinge portion 21e. The two closing steps are executed by an operator, for example. FIG. 7 illustrates a state where the covers 18 and 24 are closed. The facing wall 18a of the cover 18 covers the first portion 110 of the flat wiring member 100. The facing wall 24a of the cover 24 covers the second portion 120 of the flat wiring member 100.

In the state illustrated in FIG. 7, a first rotation step of rotating the second case 20 relative to the first case 10 is executed. In the first rotation step, the second case 20 is rotated with respect to the first case 10 about a rotation axis Cx illustrated in FIG. 7 as a rotation center. The rotation axis Cx is a straight line extending in the extending direction X between the two covers 18 and 24, for example. The rotation at this time may be executed by using a jig plate, for example. In this case, the jig plate may include: a main body that supports the first case 10; and a support member that supports the second case 20. The support member is supported by the main body so as to be rotatable about the rotation axis Cx as a rotation center.

The second case 20 is rotated relative to the first case 10 about the rotation axis Cx as a rotation center, and the second case 20 is overlapped with the first case 10. This allows the second portion 120 of the flat wiring member 100 to overlap with the first portion 110 and face the first portion 110.

FIG. 8 illustrates a state where the first rotation step is completed and the second case 20 is overlapped with the first case 10. In the present specification, with respect to the first case 10 and the second case 20, a relative position in which the two cases 10 and 20 overlap in the height direction Z is denoted as an intermediate relative position. In the intermediate relative position, the second portion 120 of the flat wiring member 100 overlaps with the first portion 110 and faces the first portion 110. Note that the height direction Z is a direction orthogonal to both the extending direction X and the width direction Y.

Since the two cases 10 and 20 rotate about the rotation axis Cx and are positioned in the intermediate relative position, the intermediate portion 130 of the flat wiring member 100 is bent along the rotation axis Cx. FIG. 9 illustrates a cross section taken along line IX-IX of FIG. 8, and FIG. 10 illustrates the flat wiring member 100 in the state of FIG. 8. As illustrated in FIGS. 9 and 10, a first folded portion 150 is formed in the intermediate portion 130 of the flat wiring member 100.

In the first folded portion 150, the intermediate portion 130 is folded along the folding line L1 in the extending direction X. The folding line L1 is a straight line extending in the extending direction X between the two covers 18 and 24, for example. The intermediate portion 130 includes: a first region 130a connected to the first portion 110; and a second region 130b connected to the second portion 120. The intermediate portion 130 is folded back such that the first region 130a and the second region 130b face each other in the height direction Z.

As illustrated in FIG. 11, the first folded portion 150 is formed so as to sandwich the cover 18 of the first case 10 by the intermediate portion 130. That is, the first region 130a and the second region 130b of the intermediate portion 130 face each other in the height direction Z across the facing wall 18a of the cover 18. The facing wall 18a includes a restricting portion 18b that protects the first folded portion 150.

As illustrated in FIG. 11, the restricting portion 18b is disposed at an end of the facing wall 18a in the width direction Y. The restricting portion 18b is a portion where the thickness of the end of the facing wall 18a is increased, and extends in the extending direction X. The cross-sectional shape of the restricting portion 18b is substantially circular. The restricting portion 18b is raised in the height direction Z toward the side opposite to the support wall 11a side. The restricting portion 18b supports the first folded portion 150 from the inside such that a bend R of the first folded portion 150 is not excessively small.

The facing wall 18a can achieve both height reduction of the first case 10 and protection of the first folded portion 150. In the facing wall 18a, portions excluding the restricting portion 18b are formed to be thin. This makes it possible to decrease an interval H1 between the first region 130a and the second region 130b in the height direction Z to achieve height reduction of the first case 10. In addition, by supporting the intermediate portion 130 in the first rotation step, an appropriate bend R can be formed in the first folded portion 150. The restricting portion 18b and the first folded portion 150 are disposed in positions shifted in the width direction Y with respect to the first portion 110 and the second portion 120. This makes it possible to decrease the interval H1 between the two regions 130a and 130b while ensuring a space for forming the appropriate bend R in the first folded portion 150.

As illustrated in FIGS. 9 and 11, the first case 10 includes a protective cover 11g that protects the intermediate portion 130 of the flat wiring member 100. The protective cover 11g is connected to the support wall 11a via a hinge portion 11f. The protective cover 11g is engaged with the support wall 11a after the first rotation step is performed. The first case 10 accommodates the intermediate portion 130 folded back in a U shape between the support wall 11a and the protective cover 11g. The facing wall 18a of the cover 18 is sandwiched inside the folded intermediate portion 130. The hinge portion 11f covers the first folded portion 150 to protect the first folded portion 150.

As illustrated in FIG. 9, the first rotation shaft 25A of the second case 20 is rotatably supported by the first shaft support portion 19A of the first case 10. The first shaft support portion 19A includes: a piece portion 19c erected in the height direction Z; and a locking portion 19d. The piece portion 19c has a slit 19e extending in the height direction Z. The end of the first rotation shaft 25A is inserted into the slit 19e and locked by the locking portion 19d.

The second rotation shaft 25B of the second case 20 is rotatably supported by the second shaft support portion 19B of the first case 10. The second shaft support portion 19B includes a slit 19f provided in a side wall 11h. The side wall 11h is disposed on both sides in the width direction Y with respect to the support wall 11a. The end of the second rotation shaft 25B is inserted into the slit 19f and rotatably supported by the side wall 11h. By inserting the two rotation shafts 25A and 25B respectively into the two shaft support portions 19A and 19B, the first case 10 and the second case 20 are rotatably coupled to each other. This constitutes a busbar module 400. The busbar module 400 includes a plurality of busbars 200 and the wire harness 1 of the embodiment.

FIG. 12 is a diagram illustrating the second rotation step. The second rotation step is executed in a factory in which the busbar module 400 is assembled to a vehicle, etc., for example. As illustrated in FIG. 12, in the second rotation step, the second case 20 is rotated relative to the first case 10 from an intermediate relative position toward the second relative position to be described below. In the second rotation step, the second case 20 rotates relative to the first case 10 about the center axis of the two rotation shafts 25A and 25B as a rotation center.

FIG. 1 illustrates a state where the second rotation step is completed and the two cases 10 and 20 are positioned in the second relative position. In the second relative position, the first case 10 and the second case 20 are aligned in a straight line shape in the extending direction X. In this state, the first portion 110 and the second portion 120 of the flat wiring member 100 are aligned in a straight line shape. In other words, the second portion 120 is positioned on an extension line of the first portion 110 in plan view. In addition, the plurality of busbars 200 are aligned in a straight line shape in the extending direction X. The cover 18 of the first case 10 covers the first portion 110 by the facing wall 18a to protect the first portion 110. The cover 24 of the second case 20 covers the second portion 120 by the facing wall 24a to protect the second portion 120.

The second rotation step is executed to form a second folded portion 160 in the flat wiring member 100. As illustrated in FIGS. 2 and 13, the second folded portion 160 is a portion folded along a folding line L2 orthogonal to the extending direction X. In the second folded portion 160, the second portion 120 is folded along the folding line L2 such that a part of the second portion 120 overlaps with the intermediate portion 130. The folding line L2 of the present embodiment is a straight line extending in the width direction Y. When the second folded portion 160 is formed, the second region 130b of the intermediate portion 130 and a proximal end 120a of the second portion 120 face each other. The proximal end 120a is an end of the second portion 120 on a side close to the intermediate portion 130.

As illustrated in FIG. 13, the proximal end 120a and the second region 130b face each other in the height direction Z across the protective cover 11g. In the portion where the protective cover 11g is disposed, the first region 130a of the intermediate portion 130, the second region 130b of the intermediate portion 130, and the proximal end 120a are aligned in the height direction Z.

The first portion 110 of the flat wiring member 100 extends from the second folded portion 160 to a first side X1 in the extending direction X. The second portion 120 extends from the second folded portion 160 to a second side X2 in the extending direction X. Therefore, in the flat wiring member 100 having a straight line shape illustrated in FIGS. 2 and 13, the second portion 120 extends on the extension line of the first portion 110 in plan view.

As illustrated in FIG. 13, the protective cover 11g includes a restricting portion 11j that protects the second folded portion 160. The restricting portion 11j is disposed at an end of the protective cover 11g on the first side X1 in the extending direction X. The restricting portion 11j is a portion where the thickness of the end of the protective cover 11g is increased, and extends in the width direction Y. The cross-sectional shape of the restricting portion 11j is substantially circular. The restricting portion 11j is raised in the height direction Z toward the side opposite to the support wall 11a. The restricting portion 11j supports the second folded portion 160 from the inside such that the bend R of the second folded portion 160 is not excessively small.

The protective cover 11g of the present embodiment can restrict the bending starting point in the second rotation step. In a case where the protective cover 11g is not provided, there is a possibility that stress concentration occurs at a corner portion 180 of FIG. 10 in the second rotation step. The corner portion 180 is a boundary between the intermediate portion 130 and the second portion 120, and is a portion where an edge of the flat wiring member 100 crosses at a substantially right angle. The restricting portion 11j of the protective cover 11g can restrict uplift of the second portion 120 so that force is less likely to act on the corner portion 180 when the two cases 10 and 20 rotate relative to each other.

FIG. 14 illustrates the flat wiring member 100 during transformation in the second rotation step. The protective cover 11g can hold the intermediate portion 130 of the flat wiring member 100 and can suppress deformation of the intermediate portion 130. In addition, the restricting portion 11j can hold the proximal end 120a of the second portion 120 and restrict uplift of the proximal end 120a. This suppresses stress concentration on the corner portion 180, enabling protection of the corner portion 180. In addition, the restricting portion 11j supports the proximal end 120a, and can form the second folded portion 160 at a desired position.

As described above, the wire harness 1 of the present embodiment includes the flat wiring member 100, the first case 10, and the second case 20. The flat wiring member 100 includes the first portion 110 having a straight line shape, the second portion 120 having a straight line shape, and the intermediate portion 130. The intermediate portion 130 is a portion connecting an end of the first portion 110 and an end of the second portion 120. The first case 10 holds the first portion 110, and the second case 20 holds the second portion 120.

The first case 10 and the second case 20 can be engaged with each other in a state where the flat wiring member 100 has a straight line shape. In the flat wiring member 100 having a straight line shape, the second portion 120 extends on the extension line of the first portion 110 in plan view. The flat wiring member 100 having a straight line shape includes the first folded portion 150 and the second folded portion 160. In the first folded portion 150, the intermediate portion 130 is folded along a folding line L1 in the extending direction X in which the first portion 110 extends. In the second folded portion 160, the second portion 120 is folded along the folding line L2 orthogonal to the extending direction X so that a part of the second portion 120 overlaps the intermediate portion 130.

The two cases 10 and 20 of the present embodiment can be engaged with each other in a state where the flat wiring member 100 formed in a U shape has a straight line shape. Therefore, in the wire harness 1 of the present embodiment, the U-shaped flat wiring member 100 can be elongated into a straight line shape.

The first case 10 of the present embodiment includes the protective cover 11g that covers the intermediate portion 130 where the first folded portion 150 is formed. Accordingly, the protective cover 11g can cover and protect the intermediate portion 130. In addition, the protective cover 11g can suppress deformation of the intermediate portion 130 and promote transformation of the flat wiring member 100 into a straight line shape.

The protective cover 11g of the present embodiment includes the restricting portion 11j. The restricting portion 11j supports the second portion 120 to restrict the position of the second folded portion 160. By restricting the position of the second folded portion 160, the restricting portion 11j can stabilize the shape of the flat wiring member 100 when the flat wiring member 100 is transformed in the second rotation step.

The method of manufacturing the wire harness 1 according to the present embodiment includes a first accommodating step, a second accommodating step, a first forming step, and a second forming step. The first accommodating step is a step of accommodating, in the first case 10, the first portion 110 having a straight line shape in the flat wiring member 100 formed in the U shape. The second accommodating step is a step of accommodating, in the second case 20, the second portion 120 having a straight line shape in the flat wiring member 100. The first accommodating step and the second accommodating step may be executed simultaneously, or one accommodating step may be executed after the other accommodating step.

The first forming step is a step of forming the first folded portion 150 in the flat wiring member 100. In the first forming step, the first case 10 and the second case 20 are overlapped with each other, and the first folded portion 150 is formed in the intermediate portion 130 of the flat wiring member 100. In the first forming step, the intermediate portion 130 is folded along a folding line L1 in the extending direction X of the first portion 110.

The second forming step is a step of forming the second folded portion 160 in the flat wiring member 100. In the second forming step, the first case 10 and the second case 20 are rotated relative to each other, and the second folded portion 160 is formed in the second portion 120. In the second forming step, the second folded portion 160 is formed along a folding line L2 orthogonal to the extending direction X so as to overlap a part of the second portion 120 with the intermediate portion 130. According to the method of manufacturing the wire harness 1 of the present embodiment, the U-shaped flat wiring member 100 can be elongated into a straight line shape.

The contents disclosed in the above embodiment can be executed in appropriate combination with each other.

A wire harness according to the present embodiment includes: the flat wiring member formed in a U shape and including the first portion having a straight line shape, the second portion having a straight line shape, and the intermediate portion connecting an end of the first portion and an end of the second portion; the first case that holds the first portion; and the second case that holds the second portion, in which the first case and the second case can be engaged with each other in a state where the flat wiring member has a straight line shape. According to the wire harness of the present embodiment, there is an effect that a flat wiring member formed in a U shape can be elongated into a straight line shape.

A wire harness manufacturing method according to the present embodiment includes: a step of accommodating, in a first case, a first portion having a straight line shape in a flat wiring member formed in a U shape; a step of accommodating, in a second case, a second portion having a straight line shape in the flat wiring member; a step of forming a first folded portion at an intermediate portion connecting the first portion and the second portion in the flat wiring member by overlapping the first case and the second case with each other and; a step of forming a second folded portion at the second portion by rotating the first case and the second case relative to each other. According to the wire harness manufacturing method according to the present embodiment, there is an effect that a flat wiring member formed in a U shape can be elongated into a straight line shape.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A wire harness comprising:
a flat wiring member formed in a U shape, the flat wiring member including a first portion having a straight line shape, a second portion having a straight line shape, and an intermediate portion connecting an end of the first portion and an end of the second portion;
a first case that holds the first portion; and
a second case that holds the second portion,
wherein the first case and the second case can be engaged with each other in a state where the flat wiring member has a straight line shape,
the flat wiring member having a straight line shape has a configuration in which the second portion extends on an extension line of the first portion in plan view,
the flat wiring member having a straight line shape includes a first folded portion and a second folded portion,
the intermediate portion is folded along a folding line in the first folded portion, the folding line extending in an extending direction in which the first portion extends, and
the second portion is folded, in the second folded portion, along a folding line orthogonal to the extending direction so as to allow a part of the second portion to overlap with the intermediate portion.

2. The wire harness according to claim 1,
wherein the first case includes a protective cover that covers the intermediate portion in which the first folded portion is formed.

3. The wire harness according to claim 2,
wherein the protective cover includes a restricting portion that supports the second portion and restricts a position of the second folded portion.

4. A wire harness manufacturing method comprising:
a step of accommodating, in a first case, a first portion having a straight line shape in a flat wiring member formed in a U shape;
a step of accommodating, in a second case, a second portion having a straight line shape in the flat wiring member;
a step of forming a first folded portion at an intermediate portion in the flat wiring member that connects the first portion and the second portion by overlapping the first case and the second case; and
a step of forming a second folded portion in the second portion by rotating the first case and the second case relative to each other,
wherein the step of forming the first folded portion folds the intermediate portion along a folding line in an extending direction of the first portion, and
the step of forming the second folded portion folds the second folded portion along a folding line orthogonal to the extending direction so as to allow a part of the second portion to overlap with the intermediate portion.
